(19) United States
(12) Patent Application Publication
(10) Pub. No.: US 2008/0144270 A1
(43) Pub. Date: Jun. 19, 2008

(54) Portable Data Storage Device

(76) Inventors: Sandro F. Dal Porto, Ladera Ranch, CA (US); Randall S. Jordan, San Juan Capistrano, CA (US); John C. Terpening, Irvine, CA (US)

Correspondence Address: STETINA BRUNDA GARRED & BRUCKER, 75 ENTERPRISE, SUITE 250, ALISO VIEJO, CA, 92656, US

(21) Appl. No.: 11/611,710

(22) Filed: Dec. 15, 2006

(51) Int. Cl. H05K 7/00

(52) U.S. Cl. 361/684

(57) ABSTRACT

A portable data storage device with shock resistant features. The portable data storage device constructed in accordance with the present invention includes an enclosure, with a data storage module mounted therein. An elastomeric shock absorbing snubber at least partially encases the data storage module. The portable data storage device includes a printed circuit board in electrical communication with the data storage module, and a Universal Serial Bus (USB) connector in electrical communication with the printed circuit board. A retainer that defines a central ventilation aperture, a front side, and a back side is mounted to the enclosure. A subassembly including the snubber and the data storage module is engaged to the front side, while the printed circuit board is engaged the back side. The ventilation aperture partitions a subassembly including the data storage module and the snubber and the printed circuit board in a spaced relationship.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND OF THE INVENTION

1. Technical Field

The present invention relates generally to portable data storage devices for use in connection with computers. More particularly, the present invention relates to hard disk drive data storage devices with enhanced shock resistance.

2. Related Art

Memory devices for use with electronic computer systems are numerous and varied. Generally, computer memory can be categorized as primary storage or secondary storage. Primary storage is directly addressable by the central processing unit, and is used to store actively processed data. While being characterized by fast access times, primary storage is typically volatile, in that power must be supplied thereto in order to retain data. Primary storage devices include random access memory (RAM), processor cache memory, processor registers, and so forth. In contrast, data transfers to secondary storage devices must be performed through input/output channels between the device and the central processing unit. Secondary storage devices have slower access times and are bulkier, but are typically non-volatile. Accordingly, secondary storage devices are used for long term or permanent storage of data. Examples thereof include hard drives, floppy drives, optical drives, and the so forth.

In addition to storing and retrieving data for one particular computer for backup purposes, secondary storage devices are also utilized for transferring data from one computer system to another. Despite increased usage of computer networks for this purpose, secondary storage devices remain popular where configuring a network is impractical or where large volumes of data are being transferred. Earlier secondary storage systems utilizing media such as floppy disks and compact disks (CDs) were separable from the access devices such as the floppy drive and the CD drive, respectively, and only the media was transported. Because of the ubiquity of CD and floppy drives on computer systems, data transfer over these media remains popular. However, because of the small capacity of floppy disks and the significant length of time required to burn a CD, alternative devices such as the flash memory device and the portable hard drive have been developed.

In these devices, the media is incorporated into the access device, so that the device is attachable to any computer system over a common interface. Earlier portable hard drives utilized either the parallel port (IEEE 1284) or the serial port (RS-232), and earlier flash memory devices conformed to the Personal Computer Memory Card International Association (PCMCIA) PC Card standard. Those in the field of removable storage were not the only ones facing the limitations present in existing interfaces between the computer and external devices, and others developing such a wide range of computer peripherals such as digital cameras, scanners, keyboards, modems, printers, and the like also faced the problems associated with slow transfer rates and other like deficiencies. Based on this collective need, the Universal Serial Bus (USB) was developed. USB provides a serial bus for connecting a multitude of devices to the computer over a common interface, providing ease of peripheral expansion, low cost, support of transfer rates up to 12 MB/Second (version 1.1) or 480 MB/Second (version 2.0) and full support for real-time voice, audio, and compressed video. Further, the USB standard represents a single model for cabling and attaching connectors, such as that all of the details of the electrical functions, including bus terminations, are isolated from the end-user. The peripherals conforming to the USB standard are self-identifying, and are dynamically attachable and re-configurable. The popularity of the USB standard is evident as most computer manufacturers now include one or more USB interfaces for external USB peripherals as part of their systems.

Taking advantage of the USB connectivity standard is a variety of data storage devices, including the aforementioned flash memory devices and hard drives. The USB flash drive is a small memory storage apparatus that interfaces with a host system through a USB connector. The apparatus uses low power, non-volatile flash memory as its storage media instead of conventional rotating hard disk media. USB flash drives as currently known typically include a USB connector, a circuit board for mounting various electrical components of the drive, and a protective exterior casing or housing which surrounds the circuit board. Typically, the electrical components mounted to the circuit board include a controller circuit, flash memory, a clock source, and various discrete components. In order to protect these components on the circuit board, the protective exterior casing projects out from the USB connector to cover such circuit board and the components mounted thereto. In further detail with respect to the flash memory, data is stored in an array of floating gate transistor “cells,” each of which corresponds to a single stored bit. Hard drives, on the other hand, are comprised of a group of stacked platters that spin past movable read/write heads at high speeds and within very close tolerances. Each of the platters stores data in a series of concentric regions referred to as tracks. When reading data to or writing data from the platters, the read/write heads rapidly move from one track to the next as data is read and written. Earlier hard drives were produced in the 5.25″, 3.5″ and 2.5″ varieties.

While having high data storage capacity, hard drives are generally unsuitable for removable storage applications. Early portable hard drives were unwieldy because of the large footprint of the hard drives themselves, and because of the additional bulk of the power supply, interface connectors, and so forth. Another limitation with portable hard drives is the likelihood of data loss stemming from minor shocks and vibrations that can cause the read/write heads in a hard disk drive to miss the track that they are supposed to read data from or write data to. This is referred to as “tracking error” and may result in corrupted data. Further, extreme shock can cause the read/write heads to contact the surface of the platters, thereby scratching the same. Though these problems occur while the hard drive is active, the moving components proved to be susceptible to damage even when the hard drive is inactive because of its delicate nature. These problems are exacerbated in the high shock, high stress environment to which a removable storage device is exposed.

As an alternative to avoid the problems with hard drives mentioned above, solid state memory devices such as flash memory drives are utilized. Such devices do not have any moving components contained therein, almost eliminating the problem of shock induced damage. Accordingly, the use of such devices in mobile data storage and transfer applications is popular. It will be appreciated, however, that flash memory devices also have a number of significant deficiencies. Flash memory is more expensive per megabyte/gigabyte than a hard disk drive. Further, although flash memory can be read or programmed a byte at a time via random access, it must be erased a “block” at a time. Once a byte within a block has been written to, it cannot be changed again until the entire block is erased. As such, notwithstanding the lack of moving components, flash memory has a finite number of erase-write cycles and thus a limited lifespan. These deficiencies are not entirely significant when data is written or erased only periodically, such as when storing music files, pictures, presentations or other data for transport between computers. However, when running applications or entire operating systems from a portable data storage device, data is being written and erased continuously, and so the limited write-erase cycles of flash memory devices is a significant limitation.

The smallest conventional hard drive used in connection with personal computers is the Microdrive, which has physical dimensions of 1.7″×1.4″×0.2″ but referred to as the 1″ form factor. There is also a 0.8″ form factor primarily used with cellular telephones. While these smaller hard drives improve mobility, particularly without the need of additional power supplies and connectors besides the attached USB connector, the problems relating to data loss stemming from shock as described above still remains. With its diminutive size and higher component density within the device, heat dissipation is also problematic, especially because of the high power consumption of conventional hard drives.

Therefore, there is a need in the art for an improved hard disk drive-based portable data storage device. Specifically, there is a need for portable hard drives capable of sustaining shocks without data loss or internal physical damage, particularly while the hard disk drive is active. Further, a portable hard drive with improved thermal dissipation features is needed in the art.

### BRIEF SUMMARY OF THE INVENTION

In accordance with the present invention, there is provided a portable data storage device having enhanced shock resistance. The portable data storage device constructed in accordance with the present invention includes an enclosure, with a data storage module mounted therein. An elastomeric shock absorbing snubber may at least partially encase the data storage module. The portable data storage device may also include a printed circuit board in electrical communication with the data storage module, and a Universal Serial Bus (USB) connector in electrical communication with the printed circuit board. A retainer that defines a central ventilation aperture, a front side, and a back side may be mounted to the enclosure. A subassembly including the snubber and the data storage module may be engaged to the front side, while the printed circuit board may be engaged the back side. The ventilation aperture may thus partition a subassembly and the printed circuit board in a spaced relationship. The data storage module may be a hard drive with rotating magnetic platters and read/write heads. There may also be included an accelerometer for signaling to the hard disk drive to park the read/write heads upon the detection of a threshold acceleration level encountered when in a freefall or upon impact, thereby substantially decreasing the likelihood of data loss and damage stemming from shock thereto. Additionally, the portable data storage device may include a low-power voltage regulator having at least 90% efficiency at a normal voltage and current output, such that heat within the enclosure is minimized. The present invention will be best understood by reference to the following detailed description when read in conjunction with the accompanying drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a perspective view of a portable data storage device in accordance with the present invention;

FIG. 2 is an exploded perspective view of the portable data storage device including an enclosure defined by an upper shell, a lower shell, and an assembly including a data storage module, a snubber, a retainer plate, a circuit board, and a USB connector;

FIG. 3 is a block diagram illustrating the electrically and logically interrelated components of the portable data storage device;

FIG. 4 is an exploded perspective view showing a first side of the components of the assembly;

FIG. 5 is a cross sectional view of the snubber taken along axis A-A of FIG. 4;

FIG. 6 is a cross sectional view of the portable data storage in accordance with the present invention, taken along axis B-B of FIG. 1;

FIG. 7 is a perspective view of the retainer plate illustrating the side thereof that engages the circuit board; and

FIG. 8 is a perspective view of the upper shell and the lower shell illustrating the internal features of the upper shell, and the exterior features of the lower shell.

Common reference numerals are used throughout the drawings and the detailed description to indicate the same elements.

### DETAILED DESCRIPTION OF THE INVENTION

The detailed description set forth below in connection with the appended drawings is intended as a description of the presently preferred embodiment of the invention, and is not intended to represent the only form in which the present invention may be constructed or utilized. It is understood that the use of relational terms such as first and second, top and bottom, and the like are used solely to distinguish one from another entity without necessarily requiring or implying any actual such relationship or order between such entities.

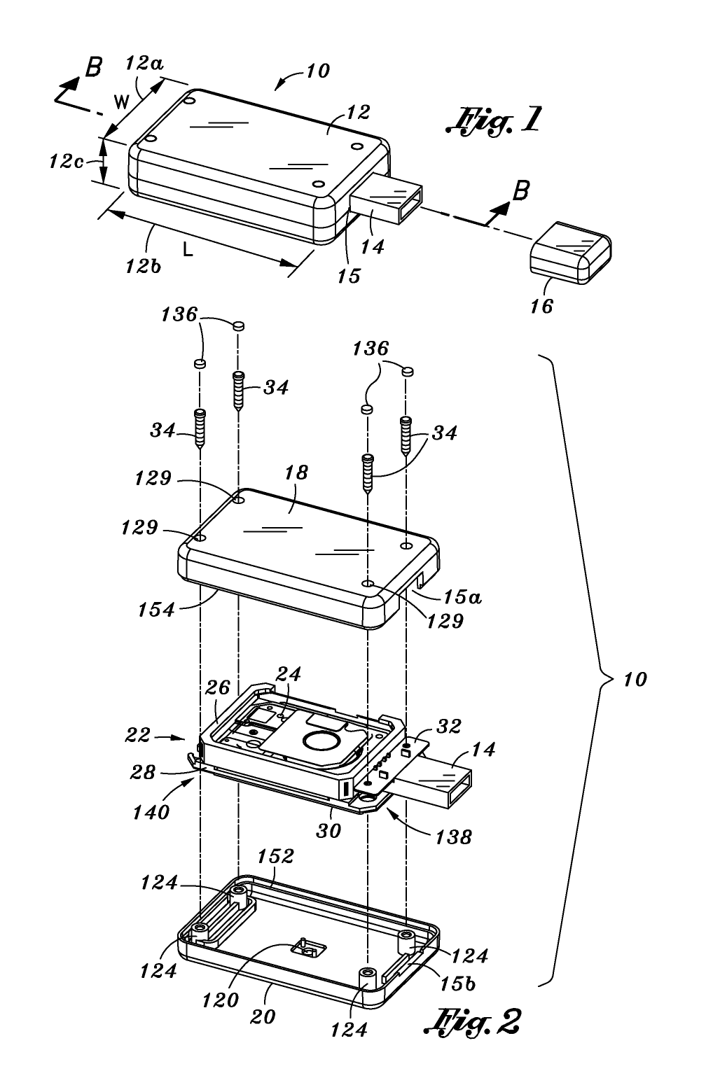

With reference now to FIG. 1, a portable data storage device 10 in accordance with one embodiment of the present invention is illustrated. The portable data storage device 10 generally includes an enclosure 12 and a Universal Serial Bus (USB) connector 14 extending therefrom. The enclosure 12 is generally defined by a width 12a, a length 12b, and a thickness 12c. While illustrated as having a rectangular configuration with arcuate edges, the footprint of the enclosure 12 may be modified to any suitable shape. Optionally, there may also be included a cap 16 configured to be fitted over the USB connector 14. As will be appreciated by one of ordinary skill in the art, the cap 16 protects the USB connector 14 from damage during transportation, and from contamination with dust and the like. It is understood that while the portable data storage device 10 is connected to a computer system for data transfer operations, specifically, when the USB connector 14 is attached to a USB socket on the computer system, the cap 16 is removed. In one embodiment, the cap 16 has a size substantially equivalent to that of the USB plug 14. Alternatively, the 16 may be sized to match the width 12a and the thickness 12c of the enclosure 12. The sizing and configuration of the 16 is a matter of design choice, and any suitable alternative including those that have locking mechanisms and the like may be readily substituted without departing from the scope of the present invention.

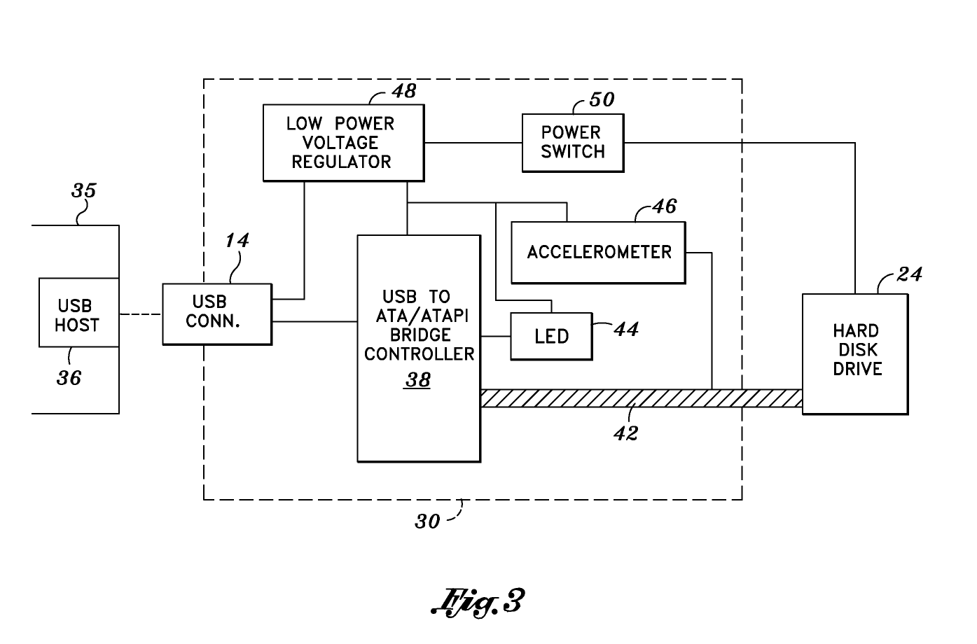

Referring now to FIG. 2, an exploded perspective view of the portable data storage device 10 is shown. In accordance with one preferred embodiment of the present invention, the enclosure 12 is comprised of an upper shell 18 and a lower shell 20. Contained within the enclosure 12, that is, between the upper shell 18 and the lower shell 20, is an assembly 22 including a data storage module or hard disk drive 24, a snubber 26 at least partially encasing the hard disk drive 24, a retainer bracket 28, a first printed circuit board 30 in electrical communication with the data storage module 24, and a second circuit board 32. The USB connector 14 is also understood to be in electrical communication with the first printed circuit board 30. The USB connector 14 protrudes from the enclosure 12 through an access slot 15, which is collectively defined by an upper access slot 15a on the upper shell 18 and a lower access slot 15b on the lower shell 20. The assembly 22 is mounted within the enclosure 12 with a set of fasteners 34 extending therethrough.

With reference to the block diagram of FIG. 3, further details relating to the functionality provided by the assembly 22 will now be described. As indicated above, the assembly 22 includes the data storage module or the hard disk drive 24. It is understood that although the terms hard disk drive and data storage module are used interchangeably, the term data storage module has broader meaning, in that it may also refer to flash memory drives and so forth. The hard disk drive 24 is comprised of rotating magnetic platters and read/write heads for reading data from and writing data to the magnetic platters. Preferably, the hard disk drive 24 is of the “Microdrive” one inch footprint having dimensions of approximately 1.7″×1.4″×0.2″. Further, the hard disk drive 24 preferably has an 8 GB capacity, although a hard disk drive of any desired capacity may be substituted.

Typically, hard disk drives and other mass storage devices are connected to a computer system over the AT Attachment/AT Attachment Packet Interface (ATA/ATAPI) standard interface, which sets forth cabling, pinouts, and other conventions. Cabling conforming to the ATA/ATAPI standard has a maximum length of 18 inches, and is comprised of forty wires, sixteen of which are dedicated for data transfer functions. The remaining wires are reserved for particular addressing and control signals, ground, and so forth. The ATA/ATAPI standard supports Direct Memory Access (DMA), whereby hardware subsystems associated with the computer system independently reads data from and writes data to the hard disk drive without such operations being performed directly by the central processing unit. Data is transferred in parallel, though modern variations also contemplate serial transmission. The ATA/ATAPI interface is widely used for the attachment of internal data storage devices because of its ubiquity and its low cost as compared to other connection solutions. In this regard, the hard disk drive 24 is also understood to include an ATA/ATAPI interface.

USB is the primary interface over which the portable data storage device 10 is connected to a computer system 35. The computer system 35 includes a USB host 36 as well as a connector for physically interfacing with the USB connector 14. As will be appreciated, data transfers over the USB interface are vastly different from data transfers over the ATA/ATAPI interface. As such, a USB to ATA/ATAPI bridge controller 38 is provided that translates the various instructions provided by the computer system 35 received as USB packets into a form recognizable by the hard disk drive 24. More specifically, between the USB connector 14 and the bridge controller 38 is a USB data channel 40 with D+ and D− lines, and between the hard disk drive 24 and the bridge controller 38 is an ATA/ATAPI data channel 42 including the various data and control lines as described above.

It is contemplated that the bridge controller 38 is compliant with the USB 2.0 specification, and supports high-speed (480 MBits/second) and full speed (12 Mbits/second) data transfer modes. Furthermore, the bridge controller 38 supports the USB mass storage device class specification in bulk-only transfer protocol, and a direct interface to the ATA and ATAPI drives with full ATA and ATAPI protocol support. Thus, the bridge controller 38 receives read/write instructions and related data from the USB host 36 through a USB connector 14 and the USB data channel 40. The instructions are processed by the bridge controller 38, translated into read/write instructions in conformance with the ATA/ATAPI standard, and transmitted to the hard disk drive 24 over the ATA/ATAPI data channel 42. In accordance with a preferred embodiment of the present invention, the bridge controller 38 may be the OTI-2118 USB 2.0 to ATA/ATAPI bridge controller produced by Ours Technology Inc. of Jhubei City, Taiwan. However, it is to be understood that the present invention does not depend on any particular bridge controller, and any suitable alternative may be readily substituted without departing from the scope of the present invention.

The portable data storage device 10 may also include an indicator 44, the operation of which is also controlled by the bridge controller 38. According to a preferred embodiment of the present invention, the indicator may be a Light Emitting Diode (LED). During operation, indicator 44 may be illuminated to signal that a connection has been established with the USB host 36. Alternatively, the indicator 44 may flash intermittently to indicate that data is being written to or read from the hard disk drive 24. It is also contemplated that the indicator 44 may be illuminated in various colors to indicate whether data is being written or being read.

The portable data storage device 10 according to an embodiment of the present invention includes an accelerometer 46 in communication with the hard disk drive 24. Upon detection of a threshold acceleration level, the accelerometer 46 signals the hard disk drive to park the read/write heads. As is well understood in the art, acceleration sensing is based upon the principle of a differential capacitance arising from acceleration induced motion of the sense element. Common mode cancellation is used to decrease errors from process variation, temperature, and environmental stress. In further detail, the accelerometer 46 triggers interrupt signals if an acceleration threshold is exceeded in any axis or if the total acceleration falls below a threshold, such as during freefall. Thus, once freefall begins but before impact, the operation of the hard disk drive 24 is halted, such that the data loss and damage to the hard disk drive 24 as described above is avoided. As shown in FIG. 3, the signaling between the accelerometer 46 and the hard disk drive 24 is performed via the ATA/ATAPI data channel 42. Any known accelerometer device having the above-described electrical signaling features may be utilized, such as those produced by Kionix, Inc. of Ithaca, N.Y.

As is commonplace in USB devices, the portable data storage device 10 draws electrical power through the USB bus as provided by the computer system 35 through the USB host 36. Power to the bridge controller 38, the indicator 44, and the accelerometer 46 is regulated by the low-power voltage regulator 48 to reduce noise and transient power spikes that may be introduced between the USB host 36 and the USB connector 14. In the particular example illustrated in FIG. 3, the USB connector 14 is connected directly to the computer system 35 so the possibility of noise being introduced into the power transmission is reduced. In alternative configurations, however, the power signal from the computer system 35 may traverse a number of hubs and extended cabling before reaching the portable data storage device 10. As such, proper regulation of the power supplied to the various components is advantageous. In further detail, the low power voltage regulator 48 is characterized by high output efficiency with minimal thermal losses. In a preferred embodiment, at a normal output voltage of 3 V and a normal load current between 150 mA and 500 mA, the low-power voltage regulator 48 has at least 90% efficiency. For example, where 1.5 W (500 mA×3V) is being dissipated, no more than 0.16 W is loss attributable to heat. The low power voltage regulator 48 may be a buck regulator produced by Enpirion, Inc. of Bridgewater, N.J., though any similar device may be substituted.

The electrical power regulated by the low power voltage regulator 48 is also supplied to the hard disk drive 24, but interposed therebetween is a power switch 50. The power switch 50 provides overcurrent protection, thermal shutdown and undervoltage lockout. As will be appreciated by one of ordinary skill in the art, the motor on the hard disk drive 24 produces a significant current draw upon startup. In order to protect the low-power voltage regulator 48, the USB host 36, and the computer system 35 from damage that may result from such an initial current spike, the power switch 50 imposes minimum output rise times. This limits electromagnetic interference and prevents upstream voltage from dropping excessively.

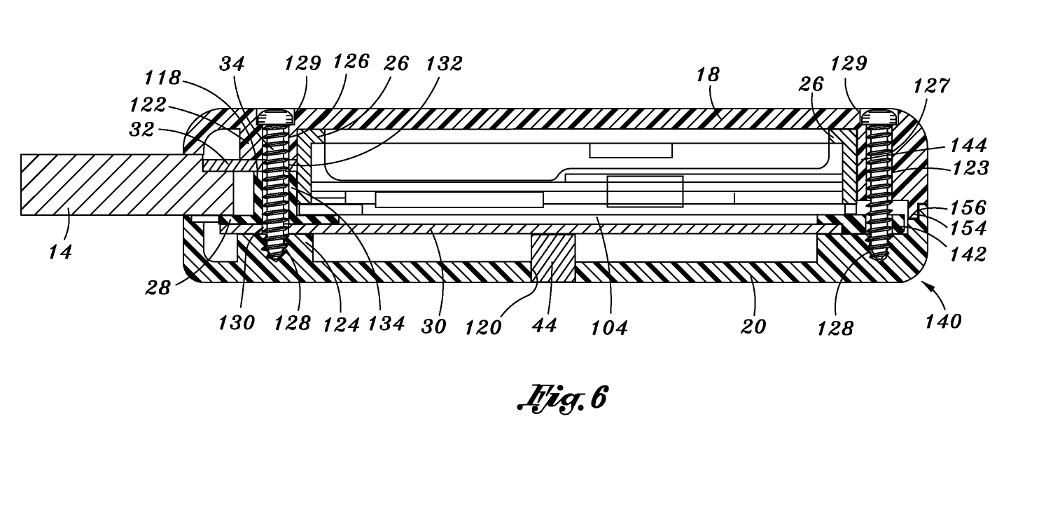

Turning now to FIGS. 3, 4 and 5, further structural details relating to the assembly 22 will be illustrated. As indicated above, the snubber 26 at least partially encases the hard disk drive 24, and cushions the corners of the same. It is contemplated that the snubber 26 is constructed of an elastomeric material such as rubber or silicone that is suitable for shock absorption applications. More particularly, the hard disk drive 24 has a cuboid configuration including a front face 52, a back face 54, a left side wall 56, a right side wall 58, a top sidewall 60, and a bottom side wall 62. A first corner edge 64 is defined by the intersection of the top sidewall 60 and the left side wall 56, and a second corner edge 66 is defined by the intersection of the left sidewall 56 and the bottom sidewall 62. Further, a third corner edge 68 is defined by the intersection of the bottom sidewall 62 and the left sidewall 58, and a fourth corner edge 70 is defined by the intersection of the left sidewall 58 and the top sidewall 60. The snubber 26 defines a first beveled corner 72, a second beveled corner 74, a third beveled corner 76, and a fourth beveled corner 78. Each of the beveled corners 72, 74, 76, and 78 of the snubber 26 cover and protect the corresponding corner edges 64, 66, 68 and 70 of the hard disk drive with the snubber 26 attached thereto as shown in FIGS. 3 and 5.

In addition to protecting the corner edges of the hard disk drive 24, in a preferred embodiment the snubber 26 shields the right side wall 58, the top and bottom sidewalls 60, 62, and partially shields the front and back faces 52, 54. More particularly, the snubber 26 is a C-shaped member that includes a top portion 80 extending in a parallel relation to a bottom portion 82. The top portion 80 and the bottom portion 82 are connected with a side portion 84 extending in perpendicular relation thereto. When the snubber 26 is attached to the hard disk drive 24, the top portion 80 faces the top sidewall 60, the bottom portion 82 faces the bottom sidewall 62, and the side portion 84 faces the right side wall 58. Thus, the snubber 26 further includes a top hook portion 86 extending in a perpendicular relationship to the top portion 80, and a bottom hook portion 88 extending in a perpendicular relationship to the bottom portion 82, both top and bottom hook portions 86, 88 facing the left sidewall 56. Accordingly, the top hook portion 86 and the bottom hook portion 88 prevents the hard disk drive 24 from becoming laterally disengaged from the snubber 26. It is understood that snubber 26 does not entirely cover the left side wall 56 because a first cabling connector 96 is disposed thereon. A cable 43 that physically embodies the ATA/ATAPI data channel 42 is attachable to the first cabling connector 96, and extends to the first printed circuit board 30, where it is attached to a second cabling connector 98. Preferably, the cable 43 is a ribbon cable.

As shown in FIG. 5, the snubber 26 is further characterized by an L-shaped cross section including an upper lip 90 and a vertical strip 94. The corners of the snubber 26 further define a corner lip 92, which extends in a generally parallel relation to the upper lip 90. When the snubber 26 is attached to the hard disk drive 24, the upper lip 90 is fixed to the front face 52, and the corner lip 92 is fixed to the back face 54. Thus, the upper lip 90 and the corner lip 92 prevent the hard disk drive 24 from becoming longitudinally disengaged from the snubber 26.

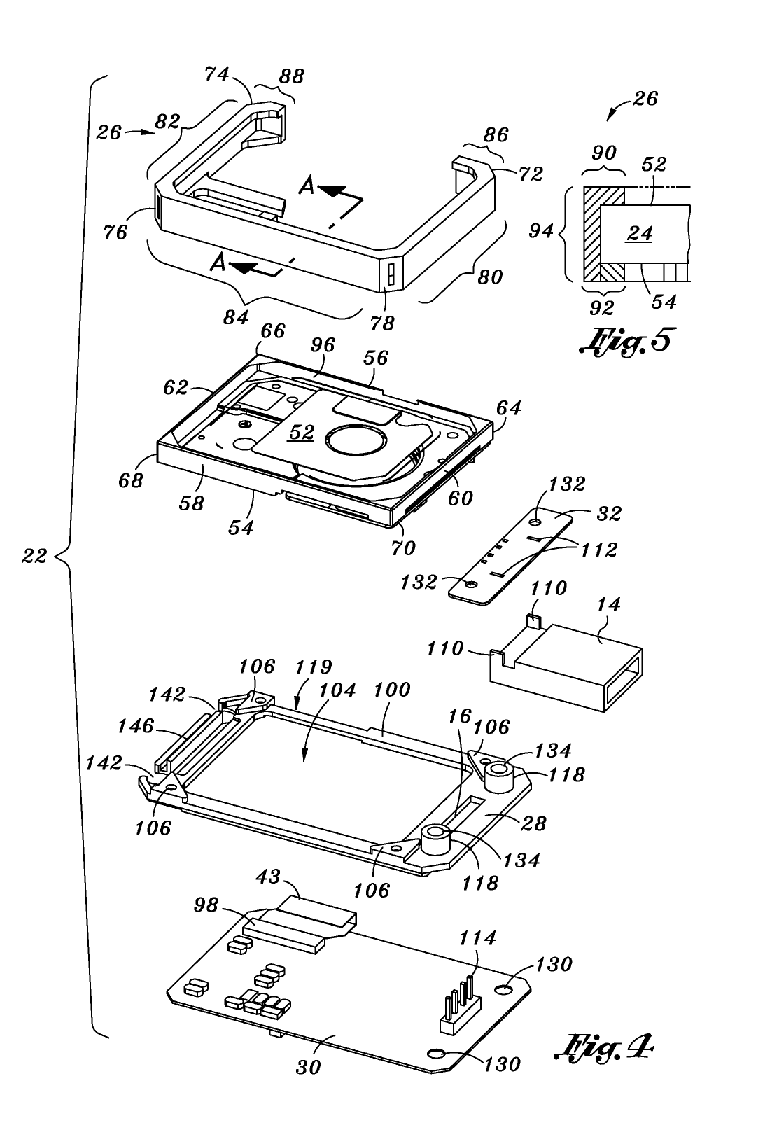

With reference to FIGS. 4 and 6, it is contemplated that the snubber 26 will isolate the hard disk drive 24 from the upper shell 18 and the retainer bracket 28, essentially suspending it within the enclosure 12. Thus, the snubber 26 reduces the potential damage that may result from force directed towards any surface of the hard disk drive 24. Force directed to the front face 52 or the back face 54 will be initially absorbed by the upper lip 90 and the corner lip 92, respectively. Furthermore, any force directed to the right sidewall 58, the top sidewall 60, or the bottom sidewall will be initially absorbed by the side portion 84, the top portion 80, or the bottom portion 82, respectively, and distributed across the entirety of the snubber 26. Any force directed to the left sidewall 56 will be absorbed by the top and bottom hook portions 86, 88. As particularly shown in FIG. 6, the snubber 26 abuts against all of the surrounding surfaces of the upper shell 18 and the retainer bracket 28, thus maximizing the dispersal of the impact force, and reducing jarring and other similar secondary shocks to the hard disk drive 24.

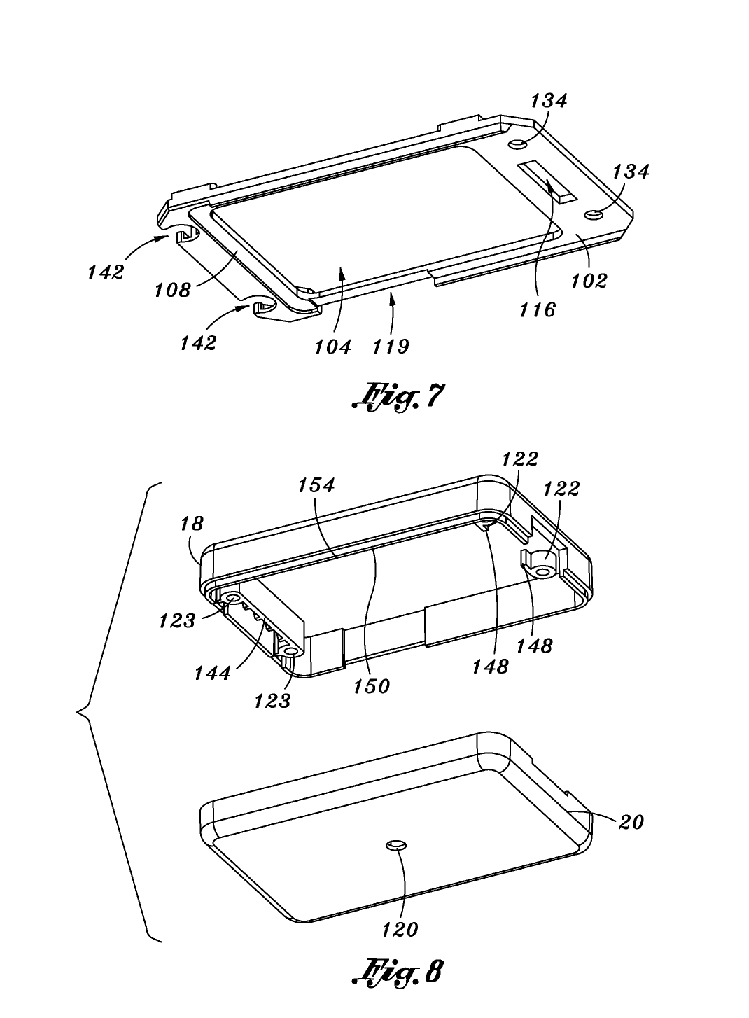

A subassembly including the snubber 26 and the hard disk drive 24 is engaged to the retainer bracket 28. As shown in FIGS. 4 and 7, the retainer bracket 28 is generally defined by a front side 100, a back side 102, and a central ventilation aperture 104. The subassembly of the hard disk drive 24 and the snubber 26 is coupled to the front side 100, which defines corner protrusions 106 each having an edge that generally correspond to the beveled corners 72, 74, 76, and 78 of the snubber 26. The corner protrusions 106 are configured for frictional engagement to snubber 26. It is contemplated that the corner protrusions 106 prevent the snubber 26 from shifting around, and firmly hold the hard disk drive 24 in place. In this regard, the corner protrusions 106 may project a suitable distance from the body of the retainer bracket 28 to fulfill this purpose. The snubber 26 is understood to rest on the retainer bracket 28. As indicated above, the first printed circuit board 30 is also engaged to the retainer bracket 28, specifically, the backside 102 thereof. The aforementioned ventilation aperture 104 thus partitions the subassembly of the hard disk drive 24 and the snubber 26 and the first printed circuit board 30 in a spaced relationship, thereby improving heat circulation characteristics within the enclosure 12. The backside 102 of the retaining bracket 28 defines an indentation 108 that corresponds to the outline of the first printed circuit board 30. Similar to the way the corner protrusions 106 on the front side 100 retain the subassembly including the hard disk drive 24 and the snubber 26, the indentation 108 frictionally retains the first printed circuit board 30 within the confines thereof. In further detail with respect to the first printed circuit board 30, it is understood that it has attached thereto the various electrical components previously described, including the bridge controller 38, the accelerometer 46, the low-power voltage regulator 48, the power switch 50, and various supporting passive components.

In one preferred embodiment, the USB connector 14 is fixedly mounted on the first printed circuit board 30 via the second circuit board 32, and is further supported by the retainer bracket 28. As will be discussed below, both the first and second printed circuit boards 30, 32 are mounted on the enclosure 12. It will be appreciated that the stress imparted upon an attachment point of the USB connector 14 during insertion and removal is reduced compared to a configuration where it is attached only at a single point, because such stress is effectively distributed between two points instead of one. Therefore, the likelihood of snapping the USB connector 14 upon inserting or removing the same at an offset angle is reduced. In further detail and with additional reference to FIG. 6, the USB connector 14 is electrically and mechanically connected to contacts disposed in the central region of the second printed circuit board 32. For additional support with respect to the attachment to the second printed circuit board 32, the USB connector 14 is provided with a pair of support tabs 110 that extend through and are frictionally retained within aligned slits 112. The second printed circuit board 32 includes traces from the contacts to jumper posts 114, which mechanically and electrically interconnect the second printed circuit board 32 to the first circuit board 30. The jumper posts 114 extend through the retainer bracket 28 via a passage 116 defined thereby and are attached to the first printed circuit board 30. The second printed circuit board 32 is further supported by a pair of opposed spacers 118 projecting from the retainer bracket 28 in perpendicular relation thereto. It is understood that that the spacers 118 prevent damage to the second printed circuit board 32 when torsional force is applied to the USB connector 14.

As previously described, the second cabling connector 98 is attached to the printed circuit board 30, and is slightly offset from the edge of the same. In order to properly route the cable 43 from the first cabling connector 96 to the second cabling connector 98 without being strained between the retainer bracket 28 and the enclosure 12, the retainer bracket 28 includes a notch 119. The notch 119 is aligned with the first cabling connector 96 and the second cabling connector 98 since the cable 43 is of a ribbon type that twisting or bending against the lengthwise axis thereof is inappropriate.

Preferably, the first printed circuit board 30 further includes the indicator 44 attached thereto, on the side facing the lower shell 20 of the enclosure 12. The lower shell 20 defines an indicator access port 120, and is coaxial with the indicator 44. Thus, the illuminations of the indicator 44 are visible from the exterior of the enclosure 12. It is understood that the indicator 44 may be disposed at any desirable location on the lower shell 20.

Having considered the structural and functional features of the assembly 22, the modality in which it is mounted within the enclosure 12, along with the structural features pertaining thereto, will now be illustrated. With reference to FIGS. 2, 6, and 8, the assembly 22 is mounted within the upper shell 18 and the lower shell 20 of the enclosure 12. According to a preferred embodiment of the present invention, the upper shell 18 defines a pair of proximal upper retaining posts 122, and the lower shell 20 defines lower retaining posts 124, at least one of the proximal upper retaining posts 122 being coaxial with a one of the lower retaining posts 124. Each of the proximal upper retaining posts 122 defines a proximal first central bore 126 extending therethrough, that is, the proximal first central bore 126 extends through the upper shell 18. Towards the exterior portion of the upper shell 18, the diameter of the proximal first central bore 126 is enlarged and defines a countersink bore 129. As particularly illustrated in FIGS. 4 and 6, the first printed circuit board 30 defines a first fastener hole 130, and the second printed circuit board 32 defines a second fastener hole 132. Furthermore, the spacer 118 defines a third central bore 134. The proximal first central bore 126, the second central bore 128, the third central bore 134, the first fastener hole 130, and the second fastener hole 132 are understood to be coaxial with respect to each other, and the diameter D therefore are understood to be equivalent. Thus, the fastener 34 may be inserted sequentially through the upper shell 18 and the one of the proximal upper retaining posts 122, the second printed circuit board 32, the retainer bracket 28, the first printed circuit board 30, and the lower retaining post 12 where the fastener 34 is frictionally engaged. Along these lines, the first printed circuit board 30 is adjacent to the lower retaining post 124, and the second printed circuit board 32 is adjacent to the proximal upper retaining post 122. In a preferred embodiment, the fastener 34 has a threaded shaft, and the head thereof is contained within the countersink bore 129. As shown in FIG. 2, the countersink bore 129 may be covered by a bore cap 136 to improve the aesthetic appearance of the portable data storage device 10.

It is understood that certain features described above are present only on the side of the applicable component that is proximate to the USB connector 14, hereinafter referred to as the proximate side 138. For instance, the retainer bracket 28 includes the spacer 118 and thus the third central bore 134 defined thereby only on the proximate side 138. Further, the first fastener hole 130 and the second fastener hole 132 exist only on the proximate side 138. Thus, in an opposed distal side 140 as shown in FIG. 6, the first printed circuit board 30 is disposed on the lower shell 20, and the upper shell 18 defines a pair of distal upper retaining posts 123. The distal side 140 of the bracket 28 further defines a pair of opposed semicircular notches 142. The distal upper retaining posts 123 are understood to have a greater length than the proximal upper retaining posts 122 because of the different support requirements, namely, the lack of the spacer 118 and the second printed circuit board 32. Each of the distal upper retaining posts 123 defines a distal first central bore 127, through which the fastener 34 is inserted and engaged to the second central bore 128. As such, the diameter of the distal first central bore 127 is understood to be equivalent to the proximal first central bore 126. Like the proximal first central bore 126, the distal first central bore 127 enlarges to define the countersink bore 129.

With reference to FIG. 8, the pair of the distal upper retaining posts 123 is connected with a truss 144 extending therebetween. As indicated above, the snubber 26 abuts against all surrounding surfaces of the upper shell 18 and the retainer bracket 28, and the truss 144 is one such surface. Along these lines, the proximal upper retaining post 122 includes a stub 148 for the snubber 26 to abut against. To maintain proper alignment of the retainer bracket 28 with respect to the enclosure 12, there is included a rail 146 that is frictionally engaged to the truss 144. Accordingly, the assembly 22 is prevented from rotating inside the enclosure 12.

As illustrated in FIGS. 2 and 9, the upper shell 18 defines a first rim 150, and the lower shell 20 defines a second rim 152. According to a preferred embodiment of the present invention, the first rim 150 is frictionally engageable to the second rim 152. More particularly, the first rim 150 includes a rim protuberance 154 that is set inwardly from the exterior of the upper shell 18, and the second rim 152 includes a rim indent 156. The rim protuberance 154 is sized such that a slight outward force is exerted upon the rim indent 156 when the two are in engagement with respect to each other. Preferably, this junction between the upper shell 18 and the lower shell 20 is sealed. According to one preferred embodiment, the sealant is silicone-based.

The portable data storage device 10 as described above fulfills the need for an improved data storage device capable of sustaining shocks without data loss or internal physical damage, and provides improved heat dissipation features. More specifically, the portable data storage device 10 is able to sustain, due in part to the unique structural features hereinbefore described, a 1500G shock while inactive or while active. The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

What is claimed is:

1. A portable data storage device, comprising:
an enclosure;
a data storage module;
an elastomeric shock absorbing snubber at least partially encasing the data storage module;
a printed circuit board in electrical communication with the data storage module;
a Universal Serial Bus (USB) connector in electrical communication with the printed circuit board; and
a retainer mounted to the enclosure and defining a central ventilation aperture, a front side, and a back side;
wherein a subassembly including the snubber and the data storage module is engaged to the front side and the printed circuit board is engaged to the back side, the ventilation aperture partitioning the subassembly and the printed circuit board in a spaced relationship.

2. The portable data storage device of claim 1, wherein:
the enclosure defines an access slot; and
the USB connector is fixedly mounted to the printed circuit board and protrudes from the enclosure through the access slot.

3. The portable data storage device of claim 1, wherein:
the snubber defines beveled corners; and
the retainer defines corner protrusions having an edge corresponding to the beveled corners of the snubber for frictional engagement thereto.

4. The portable data storage device of claim 1, wherein the back side of the retainer further defines an indentation corresponding to the outline of the printed circuit board.

5. The portable data storage device of claim 1, further comprising:
a first connector disposed along an edge of the data storage module;
a second connector disposed along an edge of the printed circuit board; and
a cable electrically interconnecting the first connector to the second connector.

6. The portable data storage device of claim 5, wherein the retainer defines an edge including an indentation notch with the first and second connectors to permit traversal of the cable.

7. The portable data storage device of claim 1, wherein the enclosure includes an upper shell defining an upper retaining post and a lower shell defining a lower retaining post, the upper retaining post being coaxial with the lower retaining post.

8. The portable data storage device of claim 7, wherein the upper retaining post defines a first central bore and the lower retaining post defines a second central bore, the first central bore extending through the upper shell.

9. The portable data storage device of claim 8, wherein:
the printed circuit board defines a fastener hole;
the retainer further includes a cylindrical protuberance with a third central bore coaxial with the first and second central bores and the fastener hole;
the portable data storage device further comprises a fastener inserted through the first central bore and into the second central bore, the fastener being frictionally engaged to the lower retaining post.

10. The portable data storage device of claim 7, wherein the upper shell defines a first rim and the lower shell defines a second rim, the first rim being frictionally engageable to the second rim.

11. The portable data storage device of claim 7, wherein the junction between the upper shell and the lower shell is sealed with a silicone sealant.

12. The portable data storage device of claim 1, wherein the data storage module is a hard disk drive with rotating magnetic platters and read/write heads, further including an accelerometer for signaling to the hard disk drive to park the read/write heads upon the detection of a threshold acceleration level.

13. The portable data storage device of claim 1, further comprising a low power voltage regulator having at least 90% efficiency at a normal voltage and current output.

14. The portable data storage device of claim 1, wherein the enclosure defines a primary face, the primary face including an indicator access port, the device further comprising:
an indicator disposed coaxially with the indicator access port.

15. A shock resistant data storage device comprising:
an enclosure;
a data storage subassembly including:
a hard disk drive; and
a snubber attached to and cushioning each corner of the hard disk drive;
a circuit board with a USB connector in electrical communication therewith;
an accelerometer in communication with the hard disk drive for momentarily suspending operations thereof upon detecting a threshold acceleration level; and
a retaining frame mounted within the enclosure, the circuit board and the data storage subassembly being coupled to the retaining frame.

16. The shock resistant data storage device of claim 15, wherein the hard disk drive has a cuboid configuration characterized by a front face, a back face, and left, right, top and bottom sidewalls.

17. The shock resistant data storage device of claim 16, wherein the snubber fully shields the right, top and bottom sidewalls, and partially shields the front face, the back face, and the right sidewall.

18. The shock resistant data storage device of claim 17, wherein the snubber is a C-shaped member includes a top portion extending in a parallel relation to a bottom portion, the top portion and the bottom portion being connected with a side portion extending in a perpendicular relation to the top and bottom portions, the top portion facing the top sidewall, the bottom portion facing the bottom sidewall, and the side portion facing the right sidewall.

19. The shock resistant data storage device of claim 17, wherein the C-shaped member has a L-shaped cross section including an upper lip in a perpendicular relation to a vertical strip, the upper lip facing the front face.

20. The shock resistant data storage device of claim 15, wherein the retaining frame defines an indentation corresponding to the outline of the circuit board and further defines a protrusion corresponding to the outline of the data storage subassembly.
